(19) United States
(12) Patent Application Publication
(10) Pub. No.: US 2024/0244762 A1
(43) Pub. Date: Jul. 18, 2024

(54) WIRING SUBSTRATE AND METHOD FOR MANUFACTURING THE SAME

(71) Applicant: IBIDEN CO., LTD., Ogaki (JP)

(72) Inventors: Nobuhisa KURODA, Ogaki (JP); Naoya MURAKAMI, Ogaki (JP)

(73) Assignee: IBIDEN CO., LTD., Ogaki (JP)

(21) Appl. No.: 18/410,477

(22) Filed: Jan. 11, 2024

(30) Foreign Application Priority Data
Jan. 12, 2023 (JP) 2023-002868

(51) Int. Cl. H05K 3/44; H05K 1/11; H05K 3/10; H05K 3/28

(52) U.S. Cl. CPC H05K 3/44; H05K 1/115; H05K 3/103; H05K 3/284; H05K 2201/0212; H05K 2201/09472

(57) ABSTRACT

A wiring substrate includes a core substrate having a cavity penetrating through the substrate, an electronic component accommodated in the cavity such that the component is positioned closer to a first surface of the substrate than a second surface of the substrate, a sealing resin filling the cavity of the substrate such that the sealing resin is covering a surface of the component on a second surface side of the substrate and that the cavity of the substrate has a portion not filled with the sealing resin on the second surface side of the substrate, and resin insulating layers including a first resin insulating layer laminated on the first surface of the substrate and a second resin insulating layer laminated on the second surface of the substrate such that a portion of the second resin insulating layer is filling the portion of the cavity not filled with the sealing resin.

### CROSS-REFERENCE TO RELATED APPLICATIONS

The present application is based upon and claims the benefit of priority to Japanese Patent Application No. 2023-002868, filed Jan. 12, 2023, the entire contents of which are incorporated herein by reference.

### BACKGROUND OF THE INVENTION

### Field of the Invention

The present invention relates to a wiring substrate and a method for manufacturing the wiring substrate.

### Description of Background Art

For example, Japanese Patent Application Publication No. 2022-139088 describes a wiring substrate in which an electronic component built in a cavity inside a core substrate is sealed with resin. The entire contents of this publication are incorporated herein by reference.

### SUMMARY OF THE INVENTION

According to one aspect of the present invention, a wiring substrate includes a core substrate having a cavity penetrating through the core substrate, an electronic component accommodated in the cavity such that the electronic component is positioned closer to a first surface of the core substrate than a second surface of the core substrate on the opposite side with respect to the first surface, a sealing resin filling the cavity of the core substrate such that the sealing resin is covering a surface of the electronic component on a second surface side of the core substrate and that the cavity of the core substrate has a portion not filled with the sealing resin on the second surface side of the core substrate, and resin insulating layers including a first resin insulating layer laminated on the first surface of the core substrate and a second resin insulating layer laminated on the second surface of the core substrate such that a portion of the second resin insulating layer is filling the portion of the cavity not filled with the sealing resin.

According to another aspect of the present invention, a method for manufacturing a wiring substrate includes forming a cavity in a core substrate, accommodating an electronic component having electrodes in the cavity, and laminating resin insulating layers including a first resin insulating layer and a second resin insulating layer such that the first resin insulating layer is laminated on a first surface of the core substrate and that the second resin insulating layer is laminated on a second surface of the core substrate. The accommodating the electronic component includes sealing an opening of the cavity with an adhesive tape on the first surface of the core substrate, fixing the electronic component such that the electrodes are in contact with the adhesive tape, and filling the cavity with a sealing resin such that the sealing resin is covering a surface of the electronic component on a second surface side of the core substrate and that the cavity of the core substrate has a portion not filled with the sealing resin on the second surface side of the core substrate, and the laminating the resin insulating layers includes filling the portion of the cavity not filled with the sealing resin with a portion of the second resin insulating layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view of a wiring substrate according to an embodiment of the present invention;

FIGS. 2A-2C are cross-sectional views illustrating a method for manufacturing a wiring substrate according to an embodiment of the present invention;

FIGS. 3A-3C are cross-sectional views illustrating a method for manufacturing a wiring substrate according to an embodiment of the present invention;

FIGS. 4A-4C are cross-sectional views illustrating a method for manufacturing a wiring substrate according to an embodiment of the present invention; and

FIGS. 5A-5C are cross-sectional views illustrating a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

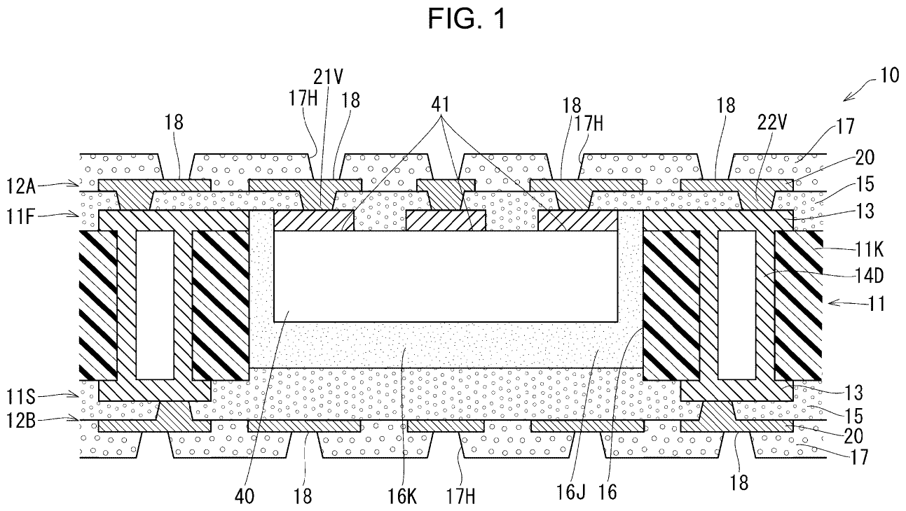

In FIG. 1, a wiring substrate 10 according to an embodiment of the present invention includes a core substrate 11, and first and second build-up layers (12A, 12B) that are respectively laminated on front and back surfaces (hereinafter referred to as an “F surface (11F)” and an “S surface (11S)”) of the core substrate 11.

The core substrate 11 has, for example, a structure in which conductive layers 13 are respectively provided on both sides of an insulating base material (11K). The insulating base material (11K) has, for example, a structure in which multiple prepregs (B-stage resin sheets that are each obtained by impregnating a core material formed of a fiber such as a glass cloth with a resin) are laminated. The conductive layers 13 are each formed to have predetermined patterns, and the conductive layers 13 adjacent to each other with the insulating base material (11K) interposed therebetween are connected by through-hole conductors (14D) penetrating the insulating base material (11K). Further, the core substrate 11 has a thickness of 1.2 mm or more.

The first and second build-up layers (12A, 12B) each include an insulating layer 15 and a conductive layer 20 laminated on the core substrate 11. The conductive layers 20 are each formed to have predetermined patterns and are respectively connected to the conductive layers 13 by via conductors (22V) penetrating the insulating layers 15.

The wiring substrate 10 includes solder resist layers 17 as outermost layers. Multiple openings (17H) are formed in the solder resist layers 17, and component mounting pads 18 are formed by portions of the conductive layers 20 exposed from the openings (17H).

In the core substrate 11 of the wiring substrate 10 of the present embodiment, a cavity 16 is formed penetrating the core substrate 11, and an electronic component 40 is accommodated in the cavity 16. The cavity 16 is formed, for example, in a rectangular parallelepiped shape. The electronic component 40 is a chip-type capacitor having a prismatic shape slightly smaller than the cavity 16 in planar shape and has electrodes 41 on an upper surface (a surface facing the F surface (11F) of the core substrate 11).

The cavity 16 does not have to be a rectangular parallelepiped space and may have a tapered shape that is reduced in width toward the F surface (11F) or S surface (11S) side of the core substrate 11. Further, without being limited to the electronic component 40, it is also possible that a metal block is accommodated in the cavity 16. Further, without being limited to a capacitor, the electronic component 40 may be, for example, a coil, a diode, a transistor, or the like, and without being limited to having a prismatic shape, the electronic component 40 may have, for example, a cylindrical shape or the like. Further, the pair of electrodes 41 of the electronic component 40 are not limited to structures provided only on the upper surface, but may be, for example, structures provided on entire circumferences of both end portions of the prismatic body.

The electronic component 40 has a thickness smaller than the thickness of the core substrate 11. For example, the core substrate 11 has a thickness of 0.4 mm or more and is 50 μm or greater than a thickness of the electronic component. Specifically, the thickness of the electronic component 40 is ⅔ or less of the thickness of the core substrate 11. In other words, the thickness of the core substrate 11 is 1.5 times the thickness of the electronic component 40. Further, the electronic component 40 is positioned close to the F surface (11F) side of the core substrate 11, and ends of the electrodes 41 and the conductive layer 13 on the F surface (11F) side are at the same height. As a result, a space (16K) is created between an end of the electronic component 40 on the S surface (11S) side and an opening upper surface of the core substrate 11 on the S surface (11S) side.

Here, a gap created between the electronic component 40 and an inner surface of the cavity 16 and a portion of the space (16K) are filled with a sealing resin (16J). The sealing resin (16J) is positioned from an end of the conductive layer 13 on the F surface (11F) side to an inner side of the opening on the S surface (11S) side in the cavity 16 and covers the electronic component 40 from the S surface (11S) side. Further, an end of the sealing resin (16J) on the F surface (11F) side is flush with the ends of the electrodes 41 and the conductive layer 13 on the F surface (11F) side.

As a material of the sealing resin (16J), for example, a thermosetting resin such as a polyimide resin or an epoxy resin is preferable. However, other resins also may be used.

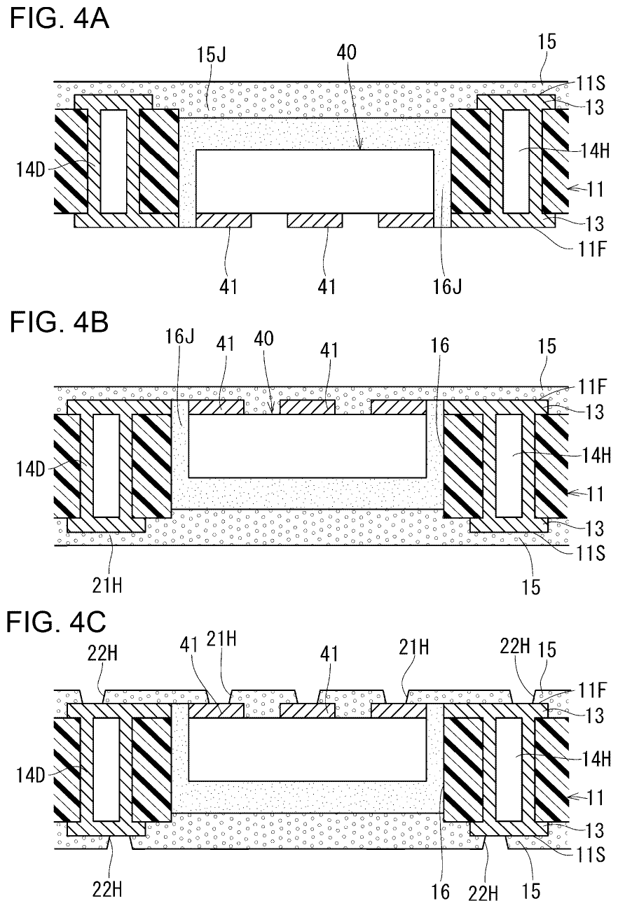

Further, the S surface (11S) side of the sealing resin (16J) in the cavity 16 is filled by the insulating layer 15 laminated on the second build-up layer (12B) side. Specifically, an insulating resin (15J) (see FIG. 4A) melted when an insulating film (a film that does not contain a core material and is formed of, for example, a thermosetting resin containing an inorganic filler) for build-up used as the insulating layer 15 is subjected to a hot pressing treatment flows into a portion of the space (16K) not filled with the sealing resin (16J), and thereby fills the portion of the space (16K).

In addition to an insulating film for a build-up substrate, the insulating layer 15 may be formed of a prepreg or a film-like epoxy resin or the like or may be formed of other materials.

Further, in a portion of the insulating layer 15 on the F surface (11F) side that covers the opening of the cavity 16, via conductors (21V) penetrating the insulating layer 15 are formed. The via conductors (21V) are connected to the electrodes 41 of the electronic component 40. On the other hand, no via conductors (21V) are formed in a portion of the insulating layer 15 on the S surface (11S) side of the core substrate 11 that covers the opening of the cavity 16.

The wiring substrate 10 of the present embodiment is manufactured as follows.

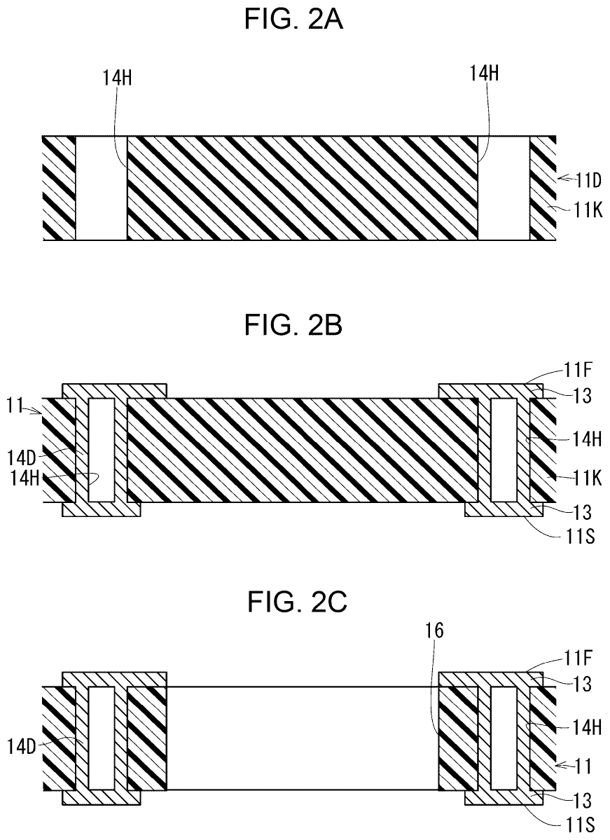

A copper-clad laminated plate (11D) in which copper foils (not illustrated) are respectively laminated on both front and back surfaces of the insulating base material (11K) is prepared; through holes (14H) are formed in the copper-clad laminated plate (11D), for example, by drilling or the like; and insides of the through holes (14H) are cleaned (desmear treatment) (FIG. 2A).

Using a subtractive method, the conductive layers 13 having predetermined patterns are respectively formed on the copper foils (not illustrated) on both the front and back surfaces of the copper-clad laminated plate (11D), and the through-hole conductors (14D) are respectively formed on inner surfaces of the through holes (14H). As a result, the core substrate 11 is formed (FIG. 2B). FIG. 2B illustrates an example of a state in which the F surface (11F) of the core substrate 11 is on an upper side, and the S surface (11S) of the core substrate 11 is on a lower side.

In the core substrate 11, the cavity 16 penetrating the core substrate 11 is formed using a router or CO₂ laser (FIG. 2C).

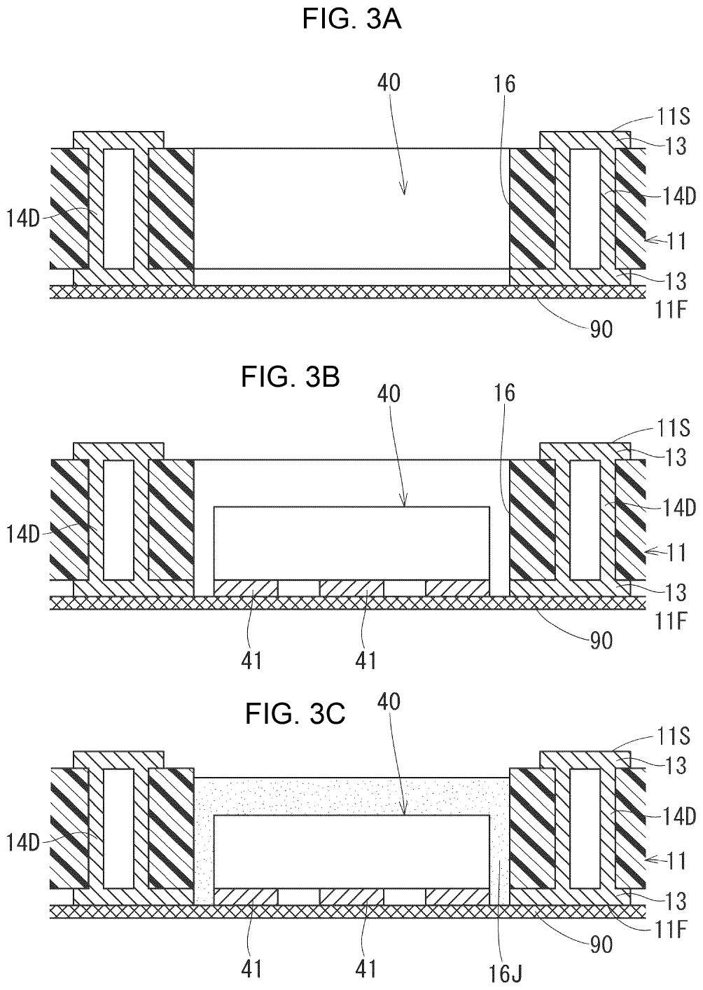

A tape 90 formed of a PET film is pasted to the F surface (11F) of the core substrate 11 so as to seal the cavity 16 (FIG. 3A). FIGS. 2A-2C, 3A-3C, and 4A each illustrate a state in which the F surface (11F) of the core substrate 11 is on a lower side.

The electronic component 40 is prepared and is placed in the cavity 16 using a mounter (not illustrated) such that the electrodes 41 face the tape 90 (FIG. 3B).

The sealing resin (16J) is filled into the cavity 16 from the S surface (11S) side of the core substrate 11. Here, the sealing resin (16J) fills the gap between the inner surface of the cavity 16 and the electronic component 40, covers the electronic component 40 from the S surface (11S) side, and fills to below the opening upper surface of the cavity 16 on the S surface (11S) side (FIG. 3C).

After the sealing resin (16J) is cured, an insulating film for a build-up substrate is laminated as the insulating layer 15 on the conductive layer 13 on the S surface (11S) side of the core substrate 11 and is hot-pressed. In this case, the insulating resin (15J) melted by the heating fills the portion of the cavity 16 that is not filled with the sealing resin (16J) (FIG. 4A). Then, the tape 90 is removed.

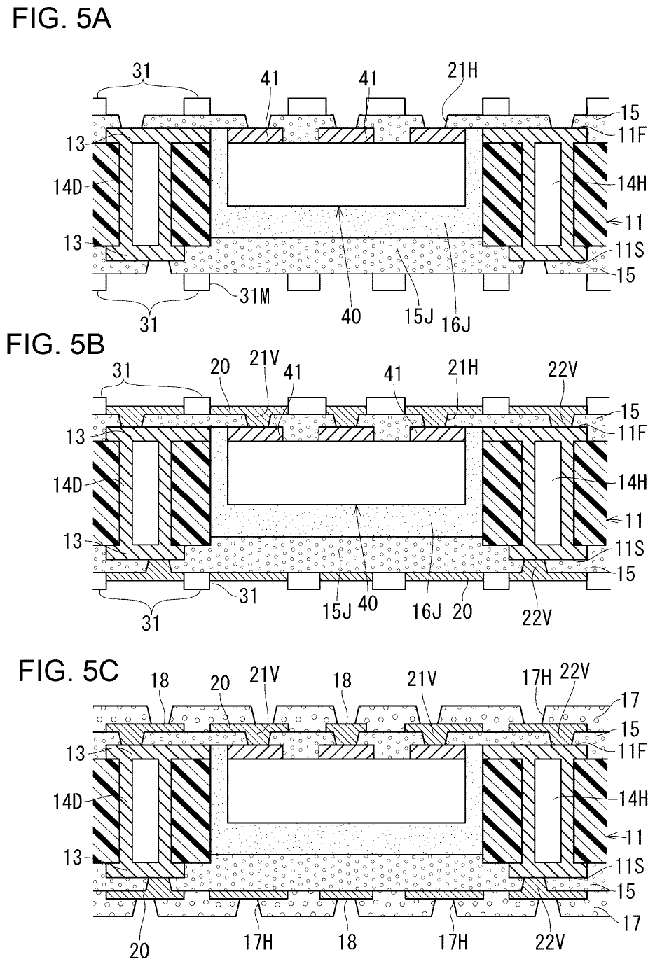

Similar to the process of (7) above, an insulating film for a build-up substrate is laminated as the insulating layer 15 on the conductive layer 13 on the F surface (11F) side of the core substrate 11 and is hot-pressed (FIG. 4B). FIG. 4B illustrates a state in which the F surface (11F) of the core substrate 11 is on a lower side, and the same applies to FIGS. 4C and 5A-5C below.

In the insulating layers 15 on both sides of the core substrate 11, multiple tapered via holes (21H, 22H) that penetrate the insulating layers 15 are formed on the conductive layers 13 and on the electrodes 41 of the electronic component 40 by laser irradiation, and insides of the via holes (21H, 22H) are cleaned (desmear treatment). The via holes (21H) are formed on the electrodes 41, and the via holes (22H) are formed on the conductive layers 13.

Next, an electroless plating treatment is performed, and an electroless plating film (not illustrated) is formed on the resin insulating layers 15 and on inner surfaces of the via holes (21H, 22H) (FIG. 4C).

A plating resist 31 having predetermined patterns is formed on the electroless plating film (not illustrated) (FIG. 5A).

When an electrolytic plating treatment is performed, the via holes (21H, 22H) are filled with electrolytic plating and the via conductors (21V, 22V) are formed (FIG. 5B).

Next, the plating resist 31 is peeled off, and the electroless plating film (not illustrated) below the plating resist 31 is removed. Then, the conductive layers 20 are formed by the remaining electroless plating film and electrolytic plating film. Next, the solder resist layers 17 are respectively laminated on upper surfaces of the conductive layers 20, and the multiple openings (17H) are formed at predetermined positions using laser or the like. Then, the pads 18 are formed by the conductive layers 20 exposed from the openings (17H) (see FIG. 5C).

The description about the structure and manufacturing method of the wiring substrate 10 of the present embodiment is as given above. In a conventional wiring substrate, sealing of an electronic component is performed by flowing an insulating resin melted by heating into a gap between the cavity and the electronic component when an insulating film as a resin insulating layer is laminated on a conductive layer of the core substrate. However, when the electronic component to be used is thin relative to the core substrate, the space in the cavity after accommodating the electronic component is large, and the amount of the insulating resin melted from the insulating film alone is insufficient. Therefore, air bubbles enter the cavity, resulting in insufficient sealing of the electronic component.

In contrast, in the wiring substrate 10 of the present embodiment, the cavity 16 is filled in advance with the sealing resin (16J) to the inner side of the S surface (11S) of the core substrate 11 before the lamination of the resin insulating layers 15, and thus, a sufficient amount of resin for sealing is ensured. According to this, air bubbles can be prevented from entering the cavity, and reliability of the sealing can be improved.

Further, a method in which the entire cavity 16 is filled with the sealing resin (16J) is also conceivable. However, in this case, there are problems such as that a process of polishing the sealing resin (16J) overflowing from the cavity 16 is required in order to ensure the flatness of the core substrate 11, and that the conductive layer 13 is also polished in the polishing process, resulting in a thinned conductive layer 13.

In contrast, in the wiring substrate 10 of the present embodiment, since the sealing resin (16J) is filled only to the inner side of the S surface (11S), the sealing resin (16J) is unlikely to overflow from the cavity 16, and since a polishing process is unnecessary, thinning of the conductive layer 13 can also be prevented.

Further, the electronic component 40 is positioned close to the F surface (11F) side of the core substrate 11 in order to shorten a connection distance to an electronic component (not illustrated) to be mounted on the F surface (11F) side of the wiring substrate 10. In a conventional method, when the space (16K) in the cavity 16 becomes larger, air bubbles are more likely to enter the cavity 16. On the other hand, the method according to the present embodiment suppresses air bubbles from entering the cavity 16, even when the space (16K) in the cavity 16 becomes larger. Further, compared to a case where air bubbles enter the F surface (11F) side of the cavity 16, the electronic component 40 is more easily held on the F surface (11F) side, and the connection between the electrodes 41 of the electronic component 40 and the via conductors (21V) is more easily maintained.

Further, since the electrodes 41 of the electronic component 40, the conductive layer 13, and the end of the sealing resin (16J) on the F surface (11F) side of the core substrate 11 are all aligned at the same height, the flatness of the wiring substrate 10 can be ensured. Further, since the sealing resin (16J) is filled up to the electrodes 41 and the end of the conductive layer 13, the position of the electronic component 40 in the cavity 16 can be easily maintained.

Further, since the thickness of the core substrate 11 is 1.2 mm or more and 1.5 or more times the thickness of the electronic component 40, a large space (16K) is formed in the cavity 16, making it easier to enjoy the effect of filling with the sealing resin (16J).

Further, by housing the electronic component 40 in the cavity 16 and filling the sealing resin (16J) with the F surface (11F) side facing downward, air in the cavity 16 is discharged from the opening on the S surface (11S) side, and thus, air bubbles are unlikely to remain inside the sealing resin (16J). Further, by temporarily fixing the electronic component 40 with the tape 90 and sealing the opening of the cavity 16 on the F surface (11F) side of the core substrate 11, it is possible not only to reliably seal the electronic component 40 at a desired position, but also to prevent the sealing resin (16J) from flowing out.

### Other Embodiments

In the above embodiment, the thickness of the core substrate 11 is 1.2 mm or more and 1.5 times the thickness of the electronic component 40. However, the core substrate 11 may have any thickness as long as the core substrate 11 is thicker than the electronic component 40.

In the above embodiment, the resin insulating layers 15 are each formed of an insulating film. However, the resin insulating layers 15 may be each formed of a paste-like thermosetting resin. With this structure, after the sealing resin (16J) is filled up to the inner side of the S surface (11S) side of the core substrate 11 in the cavity 16 and is cured by heating, the paste-like thermosetting resin is applied and cured on the conductive layers 13 and in the cavity 16.

The sealing resin (16J) and the insulating resin (15J) may be the same type of resin or may be different types of resins.

In the above embodiment, the build-up layers (12A, 12B) are each formed by laminating one conductive layer 20 and one resin insulating layer 15. However, the present invention is not limited to having this structure. For example, it is also possible to have a structure in which multiple conductive layers 20 and multiple resin insulating layers 15 are alternately laminated.

In the above embodiment, the electronic component 40 is connected to the conductive layer 20 of the first build-up layer (12A). However, it is also possible to have a structure in which the electronic component 40 is connected to the conductive layer 20 of the second build-up layer (12B), or the electronic component 40 is connected to both the conductive layer 20 of the first build-up layer (12A) and the conductive layer 20 of the second build-up layer (12B).

For example, Japanese Patent Application Publication No. 2022-139088 describes a wiring substrate in which an electronic component built in a cavity inside a core substrate is sealed with resin. In the wiring substrate described above, when the electronic component is sealed with resin, air bubbles may remain in the cavity.

A wiring substrate according to an embodiment of the present invention includes: a cavity penetrating a core substrate; an electronic component accommodated in the cavity; and resin insulating layers that are respectively laminated on front and back sides of the core substrate. The cavity is filled with a sealing resin to an inner side of a surface of at least one of the front and back sides. A portion of the cavity that is not filled with the sealing resin is filled with the resin insulating layers.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring substrate, comprising:
a core substrate having a cavity penetrating through the core substrate;
an electronic component accommodated in the cavity such that the electronic component is positioned closer to a first surface of the core substrate than a second surface of the core substrate on an opposite side with respect to the first surface;
a sealing resin filling the cavity of the core substrate such that the sealing resin is covering a surface of the electronic component on a second surface side of the core substrate and that the cavity of the core substrate has a portion not filled with the sealing resin on the second surface side of the core substrate; and
a plurality of resin insulating layers comprising a first resin insulating layer laminated on the first surface of the core substrate and a second resin insulating layer laminated on the second surface of the core substrate such that a portion of the second resin insulating layer is filling the portion of the cavity not filled with the sealing resin.

2. The wiring substrate according to claim 1, further comprising:
a plurality of conductive layers comprising a first conductive layer laminated on the first surface of the core substrate and a second conductive layer laminated on the second surface of the core substrate such that an end of the electronic component on a first surface side is positioned at a same height with the first conductive layer and an end of the sealing resin on the first surface side.

3. The wiring substrate according to claim 2, further comprising:
a plurality of via conductors formed in the first resin insulating layer and comprising a plurality of first via conductors and a plurality of second via conductors,
wherein the electronic component has a plurality of electrodes on a surface of the electronic component on the first surface side such that end surfaces of the electrodes are positioned at the same height with the first conductive layer, and the plurality of via conductors is formed in the first resin insulating layer such that the first via conductors are connected to the electrodes of the electronic component, respectively, and that the second via conductors are connected to the first conductive layer.

4. The wiring substrate according to claim 1, wherein the core substrate has a thickness of 0.4 mm or more such that the thickness of the core substrate is 50 μm or greater than a thickness of the electronic component.

5. The wiring substrate according to claim 1, further comprising:
a plurality of build-up layers comprising a first build-up layer formed on the first surface of the core substrate and a second build-up layer formed on the second surface of the core substrate,
wherein the plurality of build-up layers is formed such that the first build-up layer includes an outermost conductive layer comprising a plurality of component mounting pads.

6. The wiring substrate according to claim 2, wherein the core substrate has a thickness of 0.4 mm or more such that the thickness of the core substrate is 50 μm or greater than a thickness of the electronic component.

7. The wiring substrate according to claim 2, further comprising:
a plurality of build-up layers comprising a first build-up layer formed on the first resin insulating layer and a second build-up layer formed on the second resin insulating layer,
wherein the plurality of build-up layers is formed such that the first build-up layer includes an outermost conductive layer comprising a plurality of component mounting pads.

8. The wiring substrate according to claim 3, wherein the core substrate has a thickness of 0.4 mm or more such that the thickness of the core substrate is 50 μm or greater than a thickness of the electronic component.

9. The wiring substrate according to claim 3, further comprising:
a plurality of build-up layers comprising a first build-up layer formed on the first resin insulating layer and a second build-up layer formed on the second resin insulating layer,
wherein the plurality of build-up layers is formed such that the first build-up layer includes an outermost conductive layer comprising a plurality of component mounting pads.

10. The wiring substrate according to claim 4, further comprising:
a plurality of build-up layers comprising a first build-up layer formed on the first resin insulating layer and a second build-up layer formed on the second resin insulating layer,
wherein the plurality of build-up layers is formed such that the first build-up layer includes an outermost conductive layer comprising a plurality of component mounting pads.

11. The wiring substrate according to claim 1, wherein the sealing resin includes a thermosetting resin.

12. The wiring substrate according to claim 1, wherein the sealing resin includes a thermosetting resin comprising one of a polyimide resin and an epoxy resin.

13. The wiring substrate according to claim 1, wherein the core substrate has a thickness of 1.2 mm or more such that the thickness of the core substrate is 1.5 times a thickness of the electronic component or more.

14. The wiring substrate according to claim 2, wherein the core substrate has a thickness of 1.2 mm or more such that the thickness of the core substrate is 1.5 times a thickness of the electronic component or more.

15. The wiring substrate according to claim 3, wherein the core substrate has a thickness of 1.2 mm or more such that the thickness of the core substrate is 1.5 times a thickness of the electronic component or more.

16. The wiring substrate according to claim 5, wherein the core substrate has a thickness of 1.2 mm or more such that the thickness of the core substrate is 1.5 times a thickness of the electronic component or more.

17. A method for manufacturing a wiring substrate, comprising:
forming a cavity in a core substrate;
accommodating an electronic component having a plurality of electrodes in the cavity; and
laminating a plurality of resin insulating layers comprising a first resin insulating layer and a second resin insulating layer such that the first resin insulating layer is laminated on a first surface of the core substrate and that the second resin insulating layer is laminated on a second surface of the core substrate,
wherein the accommodating the electronic component includes sealing an opening of the cavity with an adhesive tape on the first surface of the core substrate, fixing the electronic component such that the electrodes are in contact with the adhesive tape, and filling the cavity with a sealing resin such that the sealing resin is covering a surface of the electronic component on a second surface side of the core substrate and that the cavity of the core substrate has a portion not filled with the sealing resin on the second surface side of the core substrate, and the laminating the resin insulating layers includes filling the portion of the cavity not filled with the sealing resin with a portion of the second resin insulating layer.

18. The method for manufacturing a wiring substrate according to claim 17, further comprising:
forming a plurality of via conductors in the first resin insulating layer such that the plurality of via conductors includes a plurality of first via conductors and a plurality of second via conductors,
wherein the plurality of via conductors is formed in the first resin insulating layer such that the first via conductors are connected to the electrodes of the electronic component, respectively, and that the second via conductors are connected to the first conductive layer.

19. The method for manufacturing a wiring substrate according to claim 17, further comprising:
forming a plurality of build-up layers such that the plurality of build-up layers includes a first build-up layer formed on the first surface of the core substrate and a second build-up layer formed on the second surface of the core substrate,
wherein the plurality of build-up layers is formed such that the first build-up layer includes an outermost conductive layer comprising a plurality of component mounting pads.

20. The method for manufacturing a wiring substrate according to claim 18, further comprising:
forming a plurality of build-up layers such that the plurality of build-up layers includes a first build-up layer formed on the first surface of the core substrate and a second build-up layer formed on the second surface of the core substrate,
wherein the plurality of build-up layers is formed such that the first build-up layer includes an outermost conductive layer comprising a plurality of component mounting pads.
